(19) United States
(12) Patent Application Publication
(10) Pub. No.: US 2008/0157826 A1
(43) Pub. Date: Jul. 3, 2008

(54) VOLTAGE DRIVING CIRCUIT

(75) Inventors: Ming-Daw Chen, Hsinchu City (TW); Shyh-Shyuan Sheu, Taichung (TW); Wei-Chun Chang, Tainan (TW); Keng-Li Su, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: INDUSTRIAL TECHNOLOGY RESEARCH INSTITUTE, Hsinchu (TW)

(21) Appl. No.: 11/739,114

(22) Filed: Apr. 24, 2007

(30) Foreign Application Priority Data
Dec. 29, 2006 (TW) 95149966

(51) Int. Cl. H03K 3/00

(52) U.S. Cl. 327/108

(57) ABSTRACT

A voltage driving circuit, suitable for being used in a pixel driving circuit, includes a storage unit for receiving a single-end data input signal and outputting a first voltage signal and a second voltage signal according to a content of the data input signal. The first voltage signal and the second voltage signal have different voltage levels, and the voltage levels are a high voltage level and a low voltage level, which have been adjusted to a driving-voltage requirement satisfying subsequent operations. A switch control unit receives the first voltage signal and the second voltage signal and outputs an output-voltage signal at an output terminal based on a determination from at least one control signal. The output-voltage signal is the high voltage level or the low voltage level.

### CROSS-REFERENCE TO RELATED APPLICATION

This application claims the priority benefit of Taiwan application serial no. 95149966, filed Dec. 29, 2006. All disclosure of the Taiwan application is incorporated herein by reference.

### BACKGROUND OF THE INVENTION

1. Field of the Invention

The present invention relates to a voltage driving circuit. More particularly, the present invention relates to a voltage driving circuit used for, for example, driving a pixel.

2. Description of Related Art

In the image display technology, for example, the liquid crystal display (LCD) technology develops rapidly in the recent years, and begins to seize the market of the conventional cathode ray tube (CRT) displays in the field of large-sized plane TV. However, when applied to a large-sized TV, LCD at least has the disadvantages such as heavy weight, high power consumption, and inadequate yield. Therefore, another technology of liquid crystal on silicon (LCOS) emerges on demand, which displays an image by projection. As a silicon substrate is employed, the yield is high and the cost is low. To meet a market of high-resolution products and low prices, the LCOS technology must reduce the panel size to acquire more economic benefits. The size of each pixel on a display panel determines the final size of the panel. If an analog driving mode is adopted to drive the pixels, a high-voltage process is needed, and the element size is large and cannot be reduced. Thus, for a high-resolution LCOS product, the pixels are driven by a digital driving circuit of a low-voltage process, so as to reduce the size of the panel. However, as the digital driving circuit has many elements and is highly complicated, if the process remains the same, it is still difficult to reduce the current size.

In a conventional art, a double-end driving mode is generally employed to drive individual pixels. FIG. 1 shows a conventional pixel driving circuit. Referring to FIG. 1, the conventional pixel driving circuit 212 includes a storage unit 300, a switch control unit 320, and a converter 340. The storage unit 300 receives a data input signal 120 and a data input signal 122 in a double-end manner, and the two signals are inverted to each other. Moreover, a write line signal 118 is input into the storage unit 300 via wires 306, 307. The storage unit 300 generates two corresponding voltage output signals 308, 310 according to the content of the data input signal 120. The voltage output signals 308, 310 function as input signals 324, 326 of the switch control unit 320. The switch control unit 320 receives two pairs of control signals at input terminals 328, 330, 332, 334, i.e., four control signals 276, 278, 280, 282. The control signal V_{SWA-P} 276 and the control signal V_{SWA-N} 278 are inverted to each other; the control signal V_{SWB-P} 280 and the control signal V_{SWB-N} 282 are inverted to each other. The switch control unit 320 outputs an output signal 322 to the converter 340 based on a determination from a control signal. The converter 340 then converts the output signal 322 into an actual pixel driving voltage V0 274, or a pixel driving voltage V1 272.

In other words, the converter 340 of the conventional pixel driving circuit 212 mainly selects a V1 voltage (high voltage level) or V0 voltage (low voltage level), the switch control unit 320 selects a positive terminal data or negative terminal data, and the storage unit 300 stores a binary data. The operation comprises a binary data is first stored in the storage unit 300, and the switch control unit 320 determines to output a positive or negative terminal data. Finally, the voltage is converted by the converter 340 into a V1 data (high voltage level) or V0 data (low voltage level), and is then output to a pixel.

The above conventional configuration occupies a large area, and adopts a double-end input mechanism. Additionally, a converter 340 is needed to adjust the voltage back to the actual driving voltage. For example, the detailed circuit of the storage unit 300 adopting a double-end input mechanism is shown in FIG. 2. For the storage unit 300 adopting a double-end input mechanism, the complementary data input signal B_{POS} 120 and data input signal B_{NEG} 122 are input simultaneously. Afterward, data is stored by a latch circuit constituted by transistors 606, 608, 610, 612. Transistors 604 and 602 are turned on or off under the control of the write line signal 118, so as to determine whether to input a data. However, due to double-end data, one more wire is needed on the circuit layout, which occupies more area.

Therefore, in addition to adopting a double-end input data mechanism, the conventional pixel driving circuit 212 needs a converter 340 for adjusting the voltage to a driving voltage, thus taking a large area.

### SUMMARY OF THE INVENTION

The present invention provides a voltage driving circuit, in which the storage unit is designed to have data input in a single-end input manner.

The present invention provides a voltage driving circuit, in which the storage unit is designed to be able to adjust to an actual driving voltage, thus making a subsequent converter unnecessary.

A voltage driving circuit, suitable for being used in a pixel driving circuit, includes a storage unit for receiving a single-end data input signal and outputting a first voltage signal and a second voltage signal according to a content of the data input signal. The first voltage signal and the second voltage signal have different voltage levels, and the voltage levels are a high voltage level and a low voltage level, which have been adjusted to a driving-voltage requirement satisfying subsequent operations. A switch control unit receives the first voltage signal and the second voltage signal and outputs an output-voltage signal at an output terminal based on a determination from at least one control signal. The output-voltage signal is the high voltage level or the low voltage level.

Another voltage driving circuit, suitable for being used in a pixel driving circuit, includes a storage unit for receiving a single-end data input signal and outputting a high level voltage signal and a low level voltage signal according to a content of the data input signal. A switch control unit receives the high level voltage signal and the low level voltage signal and outputs an output-voltage signal at an output terminal based on a determination from at least one control signal. The output-voltage signal is the high level voltage signal or the low level voltage signal. A converter receives and converts the output-voltage signal output from the output terminal into an actual operating voltage value.

According to the present invention, at least the area taken by the circuit can be reduced by adopting the single-end input manner. Further, according to the present invention, the voltage of the signals has been adjusted to a driving voltage value by the storage unit, so a converter is unnecessary based on practical demands. However, if the storage unit does not adjust the voltage of the signals to a driving voltage value, the design of a converter is needed.

In order to make the aforementioned and other objectives, features, and advantages of the present invention comprehensible, preferred embodiments accompanied with figures are described in detail below.

### BRIEF DESCRIPTION OF THE DRAWINGS

FIG. 1 is a conventional pixel driving circuit.

FIG. 2 is a detailed schematic circuit diagram of a storage unit of the conventional pixel driving circuit in FIG. 1.

FIG. 3 is a schematic block diagram of a voltage driving circuit according to an embodiment of the present invention.

FIG. 4 is a schematic block diagram of a voltage driving circuit according to an embodiment of the present invention.

FIG. 5 is a schematic diagram of a voltage driving circuit according to an embodiment of the present invention.

FIG. 6 is a schematic timing diagram of the operating signal of the circuit in FIG. 5.

FIG. 7 is a schematic diagram of another voltage driving circuit according to an embodiment of the present invention.

FIG. 8 is a schematic timing diagram of the operating signal of the circuit in FIG. 7.

### DESCRIPTION OF EMBODIMENTS

The present invention relates to a voltage driving circuit. The voltage driving circuit can output a corresponding voltage signal according to an input binary data. The voltage driving circuit of the present invention is also useful in a pixel driving circuit in a digital display device, so as to apply an operating voltage to a corresponding pixel. The present invention is designed to adopt a single-end input manner, and thus at least the area occupied by the circuit can be reduced. Moreover, according to the present invention, the voltage of the signals can be adjusted to a driving voltage value by the storage unit, thus making the circuit of a converter unnecessary, and further reducing the circuit area. Several embodiments are given below for illustration, but the present invention is not limited thereto. In addition, the application of the present invention is not limited to the pixel driving circuit of a digital display device.

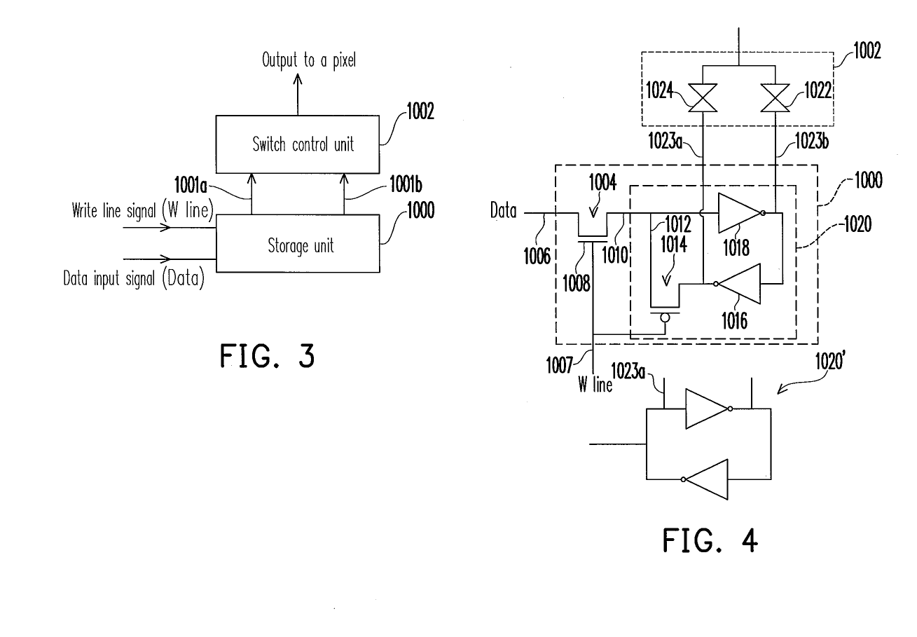

FIG. 3 is a schematic block diagram of a voltage driving circuit according to an embodiment of the present invention. Referring to FIG. 3, the voltage driving circuit of the present invention includes a storage unit 1000 and a switch control unit 1002. The storage unit 1000 receives a single-end data input signal and a write line signal. As for a general property, the storage unit 1000 of the present invention outputs a first voltage signal 1001a and a second voltage signal 1001b according to a content of the data input signal. The first voltage signal 1001a and the second voltage signal 1001b have different voltage levels. The voltage levels are a high voltage level and a low voltage level, which have been adjusted to a driving-voltage requirement satisfying subsequent operations. In other words, a high voltage source Vdd used by the storage unit 1000 has been adjusted to a high voltage level V1, and a low voltage source Vss used by the same has been adjusted to a low voltage level V0. The detailed circuit design will be described later.

The first voltage signal 1001a and the second voltage signal 1001b output by the storage unit 1000 are input into the switch control unit 1002. The switch control unit 1002 receives at least one control signal to select and output the first voltage signal 1001a or the second voltage signal 1001b as an output-voltage signal. The output-voltage signal is the high voltage level or the low voltage level, which can be output to a pixel, for example, liquid crystal pixel, for performing display driving.

FIG. 4 is a schematic block diagram of a voltage driving circuit according to an embodiment of the present invention. FIG. 4 is a circuit configuration according to FIG. 3. The storage unit 1000 receives a data input signal (Data) and a write line signal (W line). The storage unit 1000 may include, for example, a control transistor 1004 and a latch unit 1020. The control transistor 1004 has a gate 1008 for receiving the write line signal, a first source/drain 1006 for receiving the data input signal, and a second source/drain 1010 for outputting the stored content. The latch unit 1020 is coupled to the second source/drain 1010 of the control transistor 1004, for storing the content of the data input signal, for example, a bit data. After the data is stored in the latch unit 1020, a first voltage signal 1023a and a second voltage signal 1023b are output, which represent the voltage level of the bit data and a complementary voltage level thereof.

It should be noted that, the voltage of the first voltage signal 1023a and the second voltage signal 1023b has been adjusted to a voltage capable of actually driving a subsequent element, for example, a liquid crystal pixel element, during a latching process, in which the high driving voltage is V1 and the low driving voltage is V0. V1 and V0 substitute the voltage sources Vdd and Vss of the latch unit. In other words, the voltage of the first voltage signal is one of V1 and V0, and the voltage of the second voltage signal is the other one of V1 and V0 according to the input data.

Afterward, in the latch unit 1020, for example, two inverters 1016 and 1018 constitute a latch loop, i.e., a cascade loop. The input terminal of the inverter 1018 is coupled to the control transistor 1004, for inputting a data. The data input is performed by turning on the control transistor 1004 by a write signal line (W line) 1007 to input a data into the latch unit 1020. Then, the control transistor 1004 is turned off by the write signal line (W line) 1007, and thus the data is stored in the latch unit 1020. However, in order to avoid, for example, affecting the speed of data input, a protection transistor 1014 can be added to the latch loop, which has a conductivity type opposite to that of the control transistor 1004. Generally, the control transistor 1004 is, for example, an NMOS, and the protection transistor 1014 is, for example, a PMOS. The gates of the control transistor 1004 and the protection transistor 1014 are both coupled to the write signal line (W line) 1007, so the on/off states of the two transistors are just the opposite. In other words, when data is input, the protection transistor 1014 on the feedback path will be turned off, such that data can be successfully input into the forward inverter 1018. Next, when the data input is stopped, the protection transistor 1014 is converted into an open state, thus maintaining a latch loop.

However, the above latch manner is merely taken as an embodiment, and other designs are still applicable. For example, as shown by a latch unit 1020′ in the figure below, the protection transistor 1014 is unnecessary. However, in order to further enhance the efficiency, the size of the feedback inverter is reduced, for example, to achieve a slight dealy effect, such that data can be successfully written. These mentioned are some design variations, and the present invention is not limited to the above embodiments. The circuit of an inverter can be formed by serially connecting a PMOS transistor and an NMOS transistor, which will be further described later.

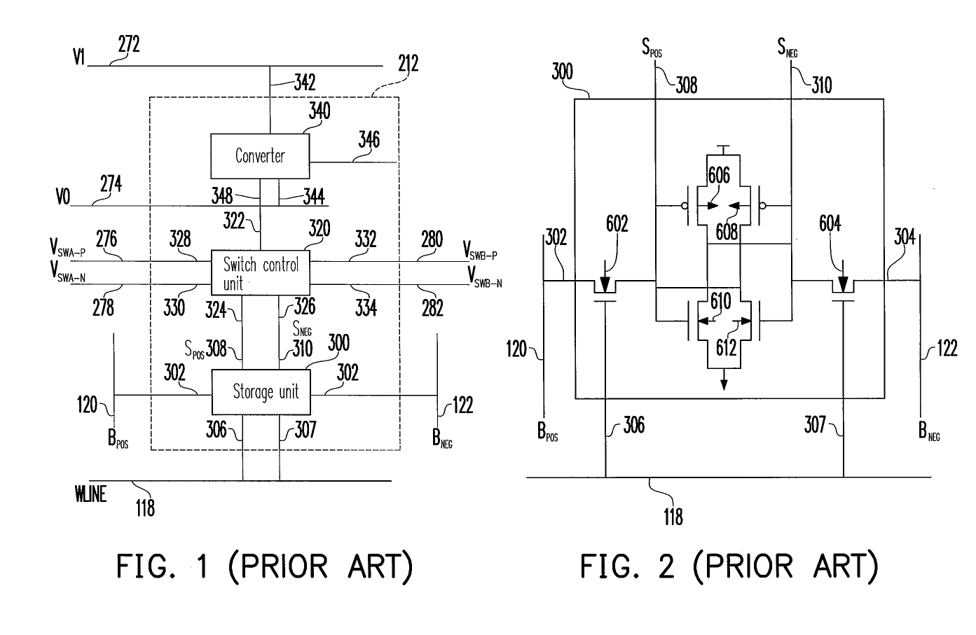

The first voltage signal 1023a and the second voltage signal 1023b output by the storage unit 1000 are input into the switch control unit 1002. The switch control unit 1002 includes, for example, a first switch 1024 and a second switch 1022, for respectively receiving the first voltage signal 1023a and the second voltage signal 1023b. The first voltage signal 1023a or the second voltage signal 1023b is output based on a determination from at least one control signal. The employed control signal is, for example, a conventionally used control signal. As shown in FIG. 1, the control signal V_{SWA-P} and the control signal V_{SWA-N} are inverted to each other; and the control signal V_{SWB-P} and the control signal V_{SWB-N} are inverted to each other. As such, together with a general pixel driving mechanism, data required to be output is selected. Furthermore, if the voltage driving circuit is used for other applications, any switch control unit with such a selection function can be adopted.

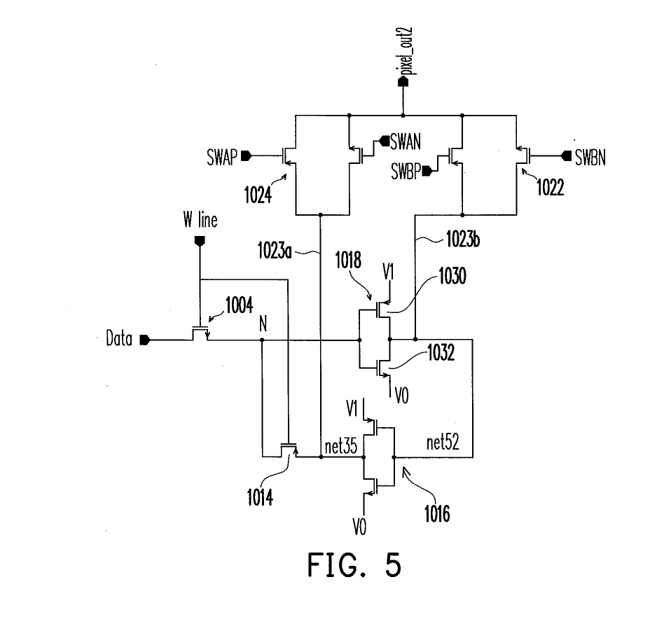

More embodiments are given below to describe the design of the circuit, and the simulated operating timing thereof. FIG. 5 is a schematic diagram of a voltage driving circuit according to an embodiment of the present invention. Referring to FIG. 5, a circuit embodiment according to FIG. 4 is shown. In the storage unit 1000, the latch unit 1020 has two inverters 1016, 1018. For example, the inverter 1018 is formed by a P-type transistor 1030 and an N-type transistor 1032, which are serially connected together via a source/drain terminal to function as an output terminal of the inverter 1018, and also can function as an output terminal of the latch unit 1020. Further, two gate terminals of the transistors 1030, 1032 are both connected to a node N. The node N functions as an input terminal of the inverter 1018, and also functions as an input terminal of the latch unit 1020. The other inverter 1016 is also connected serially, but forms a loop with the inverter 1018 in an inverted way. That is, the output terminal of the inverter 1018 is connected to the input terminal of the inverter 1016, and the output terminal (net35) of the inverter 1016 is connected to the node N through the protection transistor 1014, or directly connected to the node N. Also, for example, the output terminal (net35) of the inverter 1016 outputs the first voltage signal 1023a, and the output terminal (net52) of the inverter 1018 outputs the second voltage signal 1023b.

It should be noted that, the storage unit 1000 adopts the design of single-end input, thus reducing the circuit area. Further, the voltage sources Vdd, Vss of the inverters 1016, 1018 are set as V1, V0, which are a high voltage value and a low voltage value for actual driving. Therefore, in the present invention, a converter is not as necessary as in the conventional art, for converting a logic signal into an actual driving voltage.

Afterward, in accordance with the control in FIG. 1, the switch control unit 1002 can, for example, receive a pair of control signals with a control signal SWAP and a control signal SWAN inverted to each other, and receive a pair of control signals with a control signal SWBP and a control signal SWBN inverted from each other. The switches 1022, 1024 are constituted by a P-type transistor and an N-type transistor connected in parallel. The circuit design of the switch control unit is known to those of ordinary skill in the art, and any circuit design with the function of selection output is applicable. The output terminal (pixel_out2) of the switch control unit 1002 outputs a driving signal for, for example, driving a pixel.

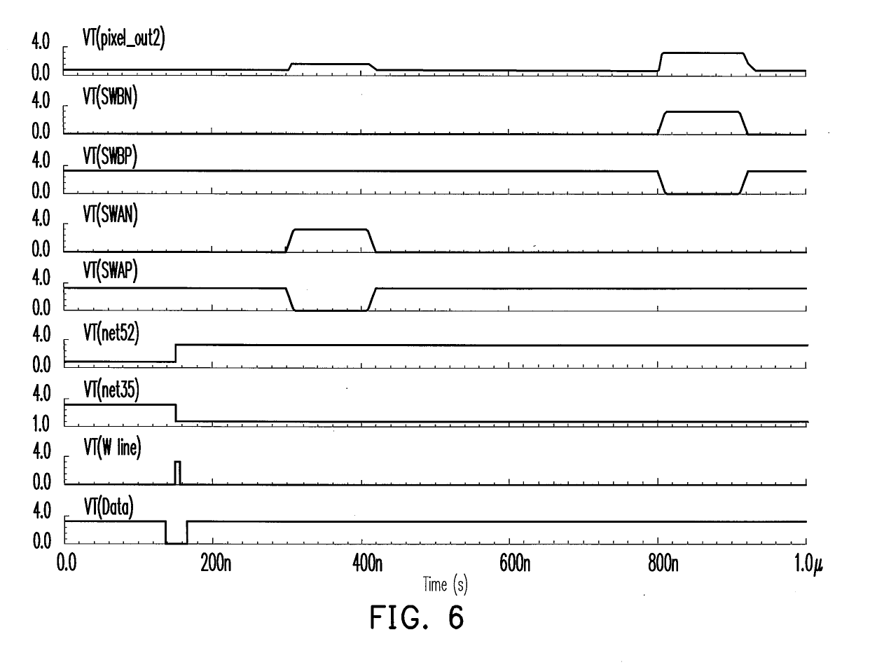

FIG. 6 is a schematic timing diagram of the operating signal of the circuit in FIG. 5. When the voltage on the write signal line (W line) is at a high level, the protection transistor 1014 is turned off, and meanwhile a “0” data is input by the data input signal (Data). At this time, the control signals SWAP, SWAN turn on the switch 1024 to output the driving voltage V0 corresponding to the “0” data. If the switch 1024 is turned off and the switch 1022 is turned on, the driving voltage V1 corresponding to a “1” data is output. In practice, those operations may vary with demands. However, the variations still fall in the specific scope of the present invention, and other variations will not be described herein again.

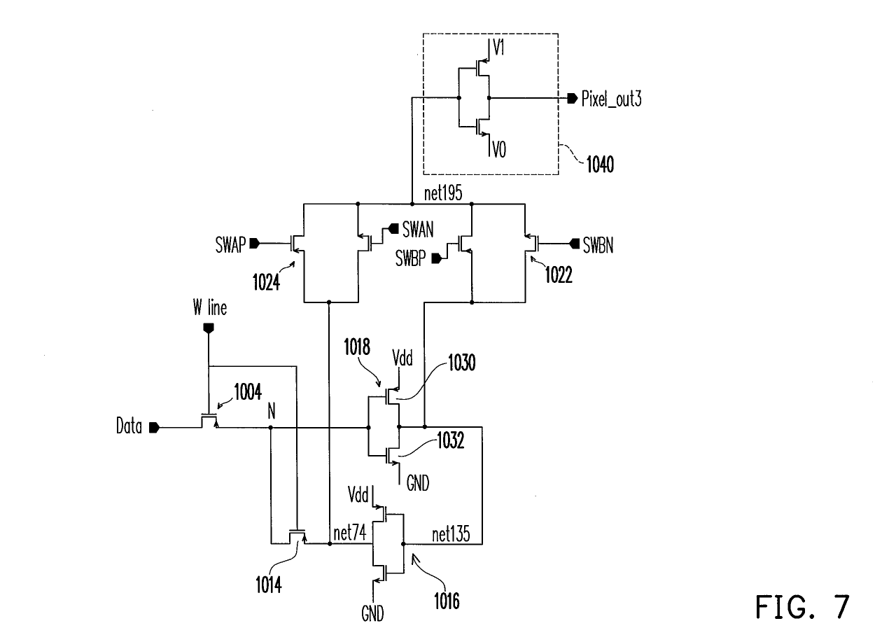

Based on the circuit block in FIG. 4, if the design still contains a converter, the single-end input manner can also be adopted. FIG. 7 is a schematic diagram of another voltage driving circuit according to an embodiment of the present invention. FIG. 7 shows a circuit configuration a little similar to that in FIG. 5. As for the design of the storage unit 1000, the single-end input manner is still maintained. However, the Vdd and of the operating voltage of the inverters do not have to be V1 and V0, and can be set according to the design of the inverters. The voltage of Vss is, for example, a grounding voltage (GND). The voltage of Vdd is determined according to the requirement of the inverter, which can be set as, for example, V1. However, due to the existence of the converter, the voltage of the Vdd is not limited to a certain value.

Next, another difference between this embodiment and the previous embodiment is illustrated below, in which a converter 1040 is included. The converter 1040 receives the output (net195) of the switch control unit 1002. The converter 1040 can, for example, have a structure similar to that of an inverter. However, the operating voltage of the converter 1040 is set as the driving voltage of V1, V0, so a desired driving voltage can be output at an output terminal (Pixel_out3).

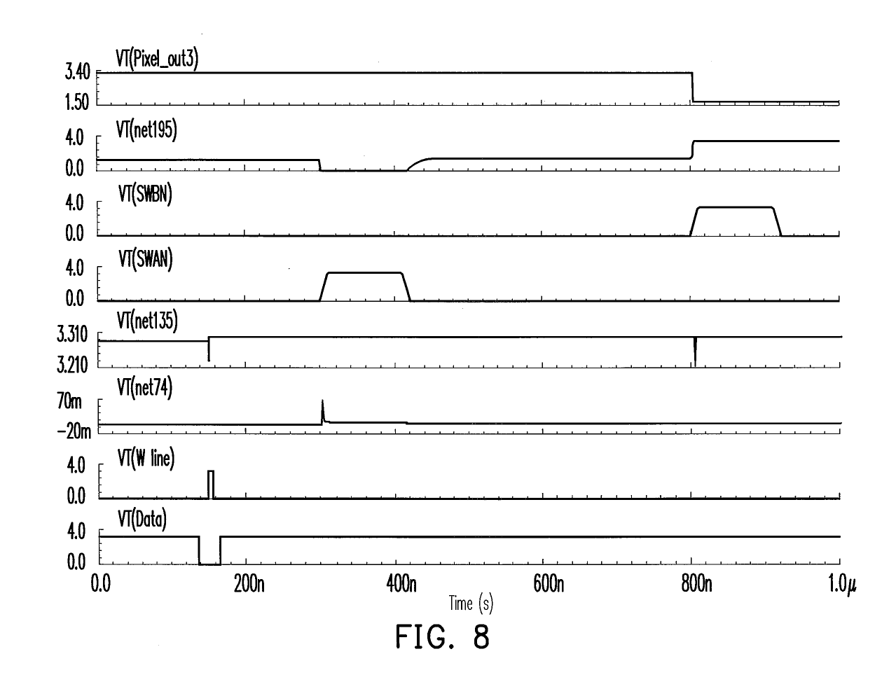

FIG. 8 is a schematic timing diagram of the operating signal of the circuit in FIG. 7. When the voltage on the write signal line (W line) is at a high level, the protection transistor 1014 is turned off, and meanwhile a “0” data is input by the data input signal (Data). The signal on a node net74 is at a low level, and the signal on a node net135 is at a high level. The node net74 and node net135 may have transient noises. When the control signal SWAN is at a high level, the switch 1024 is turned on, and the voltage corresponding to a low level is output to the node net195. If the switch 1024 is turned off and the switch 1022 is turned on, a voltage corresponding to a high level is output to the node net195. Then, the voltage is converted to an actual driving voltage by the converter 1040. In practice, those operations may vary with demands. However, the variations still fall in the specific scope of the present invention, and other variations will not be described herein again.

According to the present invention, at least the area occupied by the circuit can be reduced by adopting the single-end input design. Further, according to the present invention, the voltage of the signals has been adjusted to a driving voltage value by the storage unit, so a converter is unnecessary based on practical demands. However, if the storage unit does not adjust the voltage of the signals to a driving voltage value, the design of a converter is needed.

Though the present invention has been disclosed above by the preferred embodiments, they are not intended to limit the present invention. Anybody skilled in the art can make some modifications and variations without departing from the spirit and scope of the present invention. Therefore, the protecting range of the present invention falls in the appended claims.

What is claimed is:

1. A voltage driving circuit, comprising:
a storage unit, for receiving a single-end data input signal and outputting a first voltage signal and a second voltage signal according to a content of the data input signal, wherein the first voltage signal and the second voltage signal have different voltage levels, and the voltage levels are a high voltage level and a low voltage level, which have been adjusted to a driving-voltage requirement satisfying subsequent operations; and
a switch control unit, for receiving the first voltage signal and the second voltage signal, and outputting an output-voltage signal at an output terminal based on a determination from at least one control signal, wherein the output-voltage signal is the high voltage level or the low voltage level.

2. The voltage driving circuit as claimed in claim 1, wherein the storage unit comprises:
a control transistor, having a gate for receiving a write line signal, a first source/drain for receiving the data input signal, and a second source/drain; and
a latch unit, coupled to the second source/drain of the control transistor, for storing the content of the data input signal, and outputting the first voltage signal and the second voltage signal.

3. The voltage driving circuit as claimed in claim 2, wherein the latch unit of the storage unit comprises two inverters to constitute a latch loop.

4. The voltage driving circuit as claimed in claim 3, wherein the latch unit of the storage unit further comprises a protection transistor having a conductivity type opposite to that of the control transistor and coupled to the latch loop, and a gate of the protection transistor receives the control from the write line signal.

5. The voltage driving circuit as claimed in claim 3, wherein each of the two inverters of the latch unit of the storage unit comprises an N-type transistor and a P-type transistor connected in series.

6. The voltage driving circuit as claimed in claim 5, wherein the N-type transistor and the P-type transistor of the two inverters are connected in series, two gates of the N-type transistor and the P-type transistor are connected together to form a gate terminal, and two source/drains are connected together to form a common source/drain terminal.

7. The voltage driving circuit as claimed in claim 1, wherein the switch control unit comprises a first switch and a second switch, for respectively receiving the first voltage signal and the second voltage signal, and outputting the first voltage signal or the second voltage signal based on a determination from the control signal.

8. The voltage driving circuit as claimed in claim 7, wherein each of the first switch and the second switch of the switch control unit comprises an N-type transistor and a P-type transistor connected in parallel and disposed between the output terminal and the storage unit.

9. A voltage driving circuit, comprising:
a storage unit, for receiving a single-end data input signal and outputting a high level voltage signal and a low level voltage signal according to a content of the data input signal;
a switch control unit, for receiving the high level voltage signal and the low level voltage signal and outputting an output-voltage signal at an output terminal based on a determination from at least one control signal, wherein the output-voltage signal is the high level voltage signal or the low level voltage signal; and
a converter, for receiving and converting the output-voltage signal output from the output terminal into an actual operating voltage value.

10. The voltage driving circuit as claimed in claim 9, wherein the storage unit comprises:
a control transistor, having a gate for receiving a write line signal, a first source/drain for receiving the data input signal, and a second source/drain; and
a latch unit, coupled to the second source/drain of the control transistor, for storing the content of the data input signal, and outputting the high level voltage signal and the low level voltage signal.

11. The voltage driving circuit as claimed in claim 10, wherein the latch unit of the storage unit comprises two inverters to constitute a latch loop.

12. The voltage driving circuit as claimed in claim 11, wherein the latch unit of the storage unit further comprises a protection transistor having a conductivity type opposite to that of the control transistor and coupled to the latch loop, and a gate of the protection transistor receives the control from the write line signal.

13. The voltage driving circuit as claimed in claim 11, wherein each of the two inverters of the latch unit comprises an N-type transistor and a P-type transistor connected in series.

14. The voltage driving circuit as claimed in claim 13, wherein the N-type transistor and the P-type transistor of the two inverters are connected in series, two gates of the N-type transistor and the P-type transistor are connected together to form a gate terminal, and two source/drains are connected together to form a common source/drain terminal.

15. The voltage driving circuit as claimed in claim 9, wherein the switch control unit comprises a first switch and a second switch, for respectively receiving the high level voltage signal and the low level voltage signal, and outputting the high level voltage signal or the low level voltage signal based on a determination from at least one control signal.

16. The voltage driving circuit as claimed in claim 15, wherein each of the first switch and the second switch of the switch control unit comprises an N-type transistor and a P-type transistor connected in parallel and disposed between the output terminal and the storage unit.

17. The voltage driving circuit as claimed in claim 9, wherein the converter comprises an N-type transistor and a P-type transistor connected in series, two gates of the N-type transistor and the P-type transistor together receive the output-voltage signal of the switch control unit, and are together connected to two source/drains at a serially-connecting point to output the actual operating voltage value.

18. A voltage driving circuit, comprising:
a storage unit, for receiving a single-end data input signal and outputting a first voltage signal and a second voltage signal according to a content of the data input signal, wherein the first voltage signal and the second voltage signal have different voltage levels; and
a switch control unit, for receiving the first voltage signal and the second voltage signal, and outputting an output-voltage signal based on a determination from at least one control signal, wherein the output-voltage signal is at a high voltage level or a low voltage level according to the requirement of the data input signal.

19. The voltage driving circuit as claimed in claim 18, wherein the voltage level of the first voltage signal and the second voltage signal of the storage unit are in conformity to an actual operating voltage value.
